(19) United States
(12) Patent Application Publication
(10) Pub. No.: US 2008/0028360 A1
(43) Pub. Date: Jan. 31, 2008

(54) Methods and systems for performing lithography, methods for aligning objects relative to one another, and nanoimprinting molds having non-marking alignment features

(76) Inventors: Carl E. Picciotto, Palo Alto, CA (US); Jun Gao, Palo Alto, CA (US); Wei Wu, Palo Alto, CA (US); Zhaoning Yu, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/496,368

(22) Filed: Jul. 31, 2006

(51) Int. Cl. G06F 17/50; G03F 9/00

(52) U.S. Cl. 716/21; 430/22

(57) ABSTRACT

Methods of performing lithography include calculating a displacement vector for a lithography tool using an image of a portion of the lithography tool and a portion of a substrate and an additional image of a portion of an additional lithography tool and a portion of the substrate. Methods of aligning objects include positioning a second object proximate a first object and acquiring a first image illustrating a feature on a surface of the second object and a feature on a surface of the first object. An additional object is positioned proximate the first object, and an additional image is acquired that illustrates a feature on a surface of the additional object and the feature on the surface of the first object. The additional image is compared with the first image. Imprint molds include at least one non-marking reference feature on an imprinting surface of a mode base.

### FIELD OF THE INVENTION

The present invention generally relates to lithography techniques such as, for example, photolithography, imprint lithography, nanoimprint lithography, contact lithography, as well as precision deposition systems that employ shadowmasks. More particularly, the present invention relates to methods and systems for aligning substrates and lithography tools (such as, for example, photolithography masks, imprint molds, nanoimprint molds, and shadowmasks).

### BACKGROUND OF THE INVENTION

Lithography techniques and methods, such as, for example, photolithography, imprint lithography, nanoimprint lithography, and contact lithography may be used to fabricate structures that include features having microscale (i.e., less than about 100 microns) or nanoscale (i.e., less than about 100 nanometers) dimensions. Such structures include, for example, integrated circuits, sensors, light-emitting diodes, and nanostructures. In lithographic techniques, multi-layer structures are fabricated in a layer-by-layer process.

Briefly, in photolithography, a layer of photoresist is provided over a substrate, and a selectively patterned mask or reticle is aligned over the layer of photoresist. Selected areas of the layer of photoresist material may be exposed to electromagnetic radiation through the patterned mask or reticle, which may cause a chemical, a physical, or both a chemical and a physical transformation in the selected areas of the layer of photoresist material. In a subsequent development step, either the selected areas of the layer of photoresist material that have been exposed to the electromagnetic radiation or the other areas of the layer of photoresist material that have been shielded from the electromagnetic radiation by the mask or reticle are removed from the underlying substrate. In this manner, the selected pattern in the mask or reticle may be positively or negatively transferred to the layer of photoresist material.

The underlying substrate then may be further processed (e.g., material may be removed, deposited, doped, etc.) through the patterned layer of photoresist material, thereby forming a selectively patterned layer (corresponding to the selectively patterned mask or reticle) in or on the underlying substrate. Additional selectively patterned layers then may be formed over the previously formed selectively patterned layer using additional masks or reticles as necessary.

In order to position each layer relative to the underlying layers, the substrate and the masks or reticles typically are marked with an alignment feature or mark. As each mask or reticle is positioned over the underlying substrate, the alignment feature on the mask or reticle may be aligned with the alignment feature on the substrate before exposing the layer of photoresist material to electromagnetic radiation through the mask or reticle.

In imprint lithography (including nanoimprint lithography), a layer of deformable material (such as, for example, uncured methylmethacrylate (MMA)) may be provided over a substrate. A selectively patterned surface of an imprint mold then may be aligned over the layer of deformable material and pressed into the layer of deformable material, thereby transferring the pattern in the selectively patterned surface of the imprint mold to the layer of deformable material. The deformable material may be cured to solidify the pattern formed in the layer of deformable material. The pattern formed in the layer of deformable material may include a plurality of relatively thicker regions and relatively thinner regions in the layer of deformable material.

At least a portion of the patterned layer of deformable material then may be etched or otherwise removed until the relatively thinner regions in the patterned layer of deformable material have been substantially removed, the remaining portions of the relatively thicker regions in the layer of deformable material forming a pattern over the underlying substrate. In this manner, the selected pattern in the imprint mold may be transferred to the layer of deformable material.

The underlying substrate then may be further processed (e.g., material may be removed, deposited, doped, etc.) through the patterned layer of deformable material, thereby forming a selectively patterned layer (corresponding to the selectively patterned imprint mold) in or on the underlying substrate. Additional selectively patterned layers then may be formed over the previously formed selectively patterned layer using additional imprint molds as necessary.

As in photolithography, in order to position each layer relative to the underlying layers, the substrate and the imprint molds typically are marked with an alignment feature or mark. As each imprint mold is positioned over the underlying substrate, the alignment feature on the imprint mold is aligned with the alignment feature on the substrate before pressing the imprint mold into the layer of deformable material on the surface of the underlying substrate.

### SUMMARY OF THE INVENTION

In one aspect, the present invention includes methods of performing lithography. The methods include calculating a displacement vector for a lithography tool using an image illustrating at least a portion of the lithography tool and at least a portion of a substrate, and an additional image illustrating at least a portion of an additional lithography tool and at least a portion of the substrate.

In another aspect, the present invention includes methods of aligning objects relative to one another. The methods include providing a first object having a feature on a surface of the first object. A second object having a feature of a surface thereof is positioned proximate the first object, and a first image is acquired that illustrated the feature on the surface of the first object and the feature on the surface of the second object. At least one additional object having a feature on a surface thereof is positioned proximate the first object, and an additional image is acquired that illustrates the feature on the surface of the first object and the feature on the surface of the at least one additional object.

In yet another aspect, the present invention includes imprint molds that have at least one non-marking alignment feature on an imprinting surface of the imprint mold. In some embodiments, the at least one alignment feature may extend from the imprinting surface by a distance that is less than a substantially uniform distance by which device features protrude from the imprinting surface.

### BRIEF DESCRIPTION OF THE SEVERAL VIEWS OF THE DRAWINGS

While the specification concludes with claims particularly pointing out and distinctly claiming that which is regarded as the present invention, the advantages of this invention can be more readily ascertained from the following description of the invention when read in conjunction with the accompanying drawing in which:

FIG. 1 is a block diagram of an embodiment of a lithography system that may be used to precisely align objects relative to one another according to the present inventions

FIG. 2 is a flow-chart illustrating one example of a method for aligning objects relative to one another according to the present invention, and that may be implemented using the system illustrated in FIG. 1.

FIG. 3 is a plan view of a substrate that includes a reference feature on a surface thereof;

FIGS. 4-9 illustrate one example of a method that may be used to provide a reference feature on a surface of a substrate like that shown in FIG. 3;

FIG. 10 illustrates an embodiment of a lithography tool positioned relative to a substrate to be processed using the lithography tool;

FIG. 11 is a cross-sectional side view of the lithography tool and the substrate shown in FIG. 10;

FIG. 12A is a cross-sectional side view like that of FIG. 11 illustrating a mold alignment feature located on a back side of a lithography tool;

FIG. 12B is a cross-sectional side view like that of FIGS. 11 and 12A illustrating a mold alignment feature of a lithography tool comprising an aperture extending through the lithography tool;

FIG. 13 is a plan view of the substrate shown in FIGS. 10-11 illustrating device features formed on the surface of the substrate using the lithography tool shown therein;

FIG. 14 illustrates an additional lithography tool positioned relative to the substrate shown in FIGS. 10-11;

FIGS. 15-17 illustrate one example of a method that may be used to determine whether the additional lithography tool shown in FIG. 14 is properly aligned with the underlying substrate; and

FIG. 18 illustrates the additional lithography tool and the substrate shown in FIG. 14 properly aligned after adjusting the relative position between the additional lithography tool and the substrate;

FIG. 19 illustrates a reference mark on a substrate and an alignment mark on a lithography tool that are respectively located on the substrate and the lithography tool so as to appear intertwined in an image acquired by an imaging system; and

FIG. 20 illustrates a reference mark on a substrate and an alignment mark on a lithography tool that are respectively located on the substrate and the lithography tool so as to appear co-located in an image acquired by an imaging system.

### DETAILED DESCRIPTION OF THE INVENTION

The present invention includes methods and systems that can be used to lithographically fabricate structures and devices. By way of example and not limitation, the methods and systems described herein may be used in imprint lithography and nanoimprint lithography processes, such as, for example, those described in U.S. Pat. No. 6,432,740 to Chen, which is assigned to the assignee of the present invention. The methods and systems described herein may also be used in photolithography processes, contact lithography processes, as well as in precision deposition processes in which shadowmasks are employed.

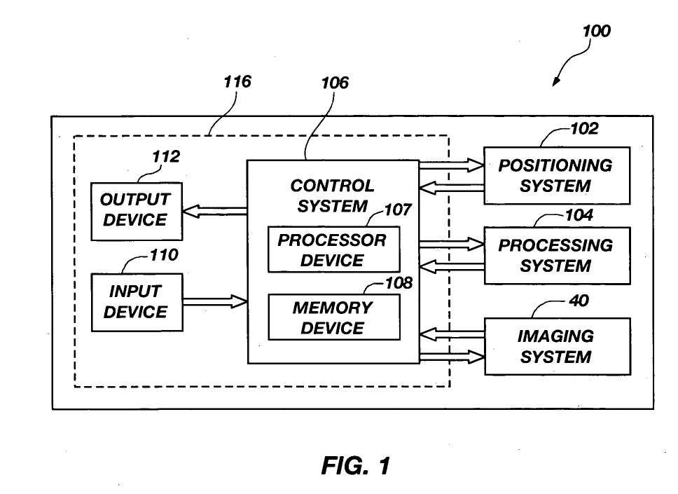

Lithography systems such as, for example, photolithography systems and nanolithography systems may be configured to perform methods that embody teachings of the present invention, and as such, also may embody teachings of the present invention. FIG. 1 is a block diagram of a lithography system 100 that embodies teachings of the present invention. As shown therein, the lithography system 100 may include a positioning system 102, an imaging system 40, a processing system 104, and a control system 106. The positioning system 102 may be configured to move a lithography tool (not shown in FIG. 1), a substrate (not shown in FIG. 1), or both a lithography tool and a substrate, so as to position a lithography tool relative to a substrate. In some embodiments, the positioning system 102 may be configured to move a plurality of lithography tools and substrates. The processing system 104 may be configured to process a substrate using lithography tools by, for example, depositing material over the substrate, removing material from the substrate, doping material on or in the substrate, etc.

By way of example and not limitation, the imaging system 40 may include an optical microscopy system, an X-Ray system, or any other imaging system or device that is capable of acquiring an image of at least a portion of a lithography tool and a portion of a substrate. The positioning system 102 may include, for example, a moveable stage (not shown) configured to support a substrate. The positioning system 102 may further include stage actuator devices (not shown) configured to move the moveable stage. Such stage actuator devices may include, for example, commercially available steppers or piezoelectric actuators. In addition to a moveable stage (or as an alternative to a moveable stage), the positioning system 102 may include a moveable tool support device configured to support a lithography tool. Such a moveable tool support device also may be moved using commercially available actuators, as previously described.

The control system 106 may include at least one electronic signal processor device 107 (e.g., a digital signal processor (DSP) device) and at least one memory device 108 (e.g., a device comprising random access memory (RAM) (e.g., static RAM (SRAM), dynamic RAM (DRAM), synchronous DRAM (SDRAM), etc.). By way of example and not limitation, the control system 106 may be or may include a computer system or a computer device such as a desktop computer or a notebook computer. In additional embodiments, the control system 106 may include a commercially available programmable logic controller or a custom-built control system 106 that is both structurally and electrically integrated with the lithography system 100.

As shown in FIG. 1, the control system 106 of the lithography system 100 may be configured to electrically communicate with both the positioning system 102 and the imaging system 40. In this configuration, the control system 106 may be configured to control the positioning system 102 and to receive information from the positioning system 102. For example, the positioning system 102 may include one or more sensors configured to sense or detect a position of a lithography tool, a substrate, or both a lithography tool and a substrate, and to relay information regarding the position to the control system 106 by way of an electrical signal. Similarly, the control system 106 may be configured to control the imaging system 40 and to receive information from the imaging system 40. For example, the imaging system 40 may be configured to transmit digital images (e.g., reference images and alignment images, as described in further detail below) to the control system 106 for analysis thereof by way of an electrical signal. In additional embodiments, the control system 106 may be configured to communicate with the positioning system 102, the imaging system 40, or both the positioning system 102 and the imaging system 40 using wireless technology (e.g., signals transmitted via electromagnetic radiation).

The lithography system 100 may further include at least one input device 110, which may be used by a person using the lithography system 100 to input information to the control system 106 or to provide commands to the control system 106. By way of example and not limitation, the input device 110 may include a computer keyboard, a keypad, a touchpad, a touchscreen, a pointing device (e.g., mouse), or any other means for inputting information or providing commands to the control system 106. In addition, the lithography system 100 may further include at least one output device 112, which may be configured to output information to a user from the control system 106. By way of example and not limitation, the output device 112 may include a graphical display device (such as, for example, a monitor or screen), a printer, a device configured to create audible sounds or alarms, or any other means for outputting information to a user by the control system 106.

As shown in FIG. 1, at least one of the input device 110 and the output device 112 may be structurally integrated with the control system 106, as represented by the broken line 116. As an example, the control system 106 may include a programmable logic controller, the input device 110 may include a keypad or touchpad of the programmable logic controller, and the output device 110 may include a liquid crystal display (LCD) screen of the programmable logic controller. Such programmable logic controllers are commercially available.

In some embodiments of the present invention, substantially all components of the lithography system 100 may be structurally integrated into or with a single structural frame or housing to provide a “stand-alone” unitary system. In other embodiments of the present invention, one or more components of the lithography system 100 may be located remote from other components of the lithography system 100. In such instances, communication may be established between the remote components, for example, by way of electrical communication over electrical wires or wireless communication using electromagnetic radiation.

As previously mentioned, the control system 106 of the lithography system 100 may be configured under control of a program to carry out methods that embody teachings of the present invention using the positioning system 102 and the imaging system 40. In other words, the lithography system 100, and in particular the control system 106 thereof, may be configured under control of a computer program to execute one or more logic sequences, which cause the lithography system 100 to execute methods that embody teachings of the present invention.

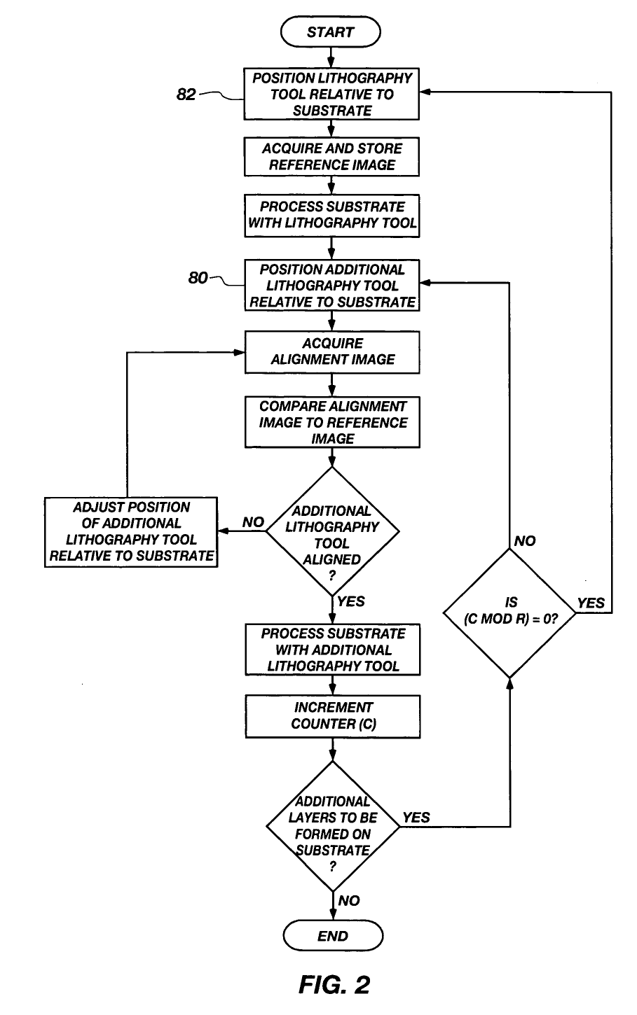

By way of example and not limitation, the control system 106 of the lithography system 100 may be configured under control of a program to execute one or more logic sequences, one of which may include a logic sequence illustrated in FIG. 2. The logical sequences illustrated in FIG. 2 may also be used as a flowchart to illustrate and describe methods that embody teachings of the present invention.

Methods that embody teachings of the present invention will be described with reference to the logical sequences illustrated in FIG. 2, together with reference to FIG. 1 and FIGS. 3 through 18.

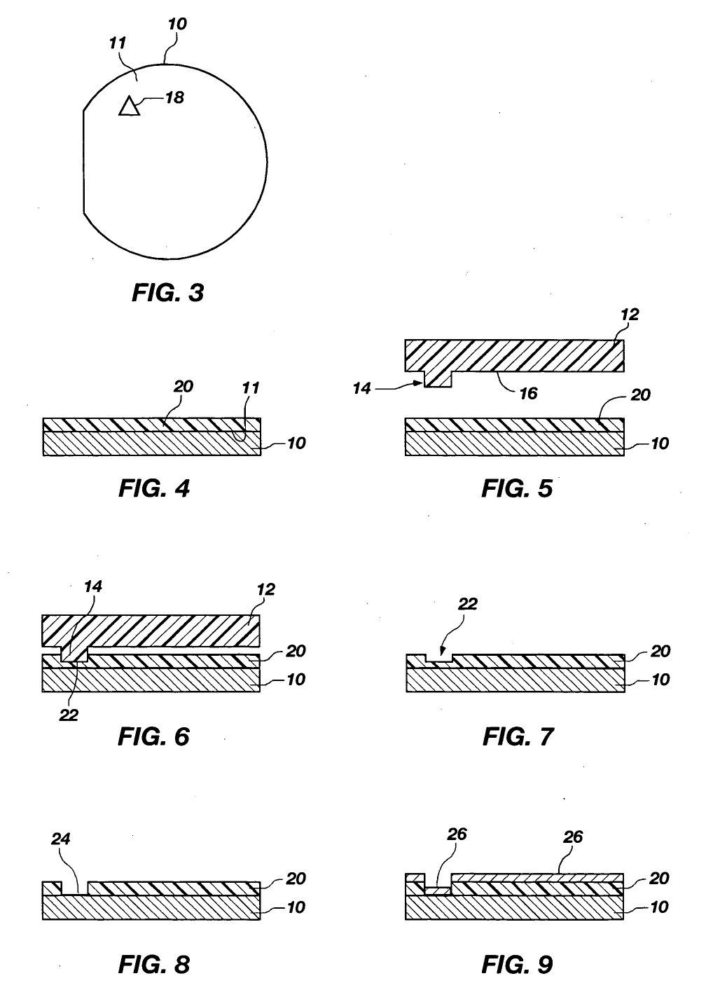

FIG. 3 illustrates a substrate 10 on or in which a structure or device may be lithographically fabricated using methods and systems that embody teachings of the present invention. The substrate 10 may include, but is not limited to, for example, a whole or partial wafer of silicon, gallium arsenide, or indium phosphide, glass, or a silicon on insulator (SOI) type substrate, such as a silicon-on-glass (SOG), silicon on ceramic (SOC), or silicon on sapphire (SOS) substrate. In order to lithographically fabricate a structure or device on the substrate 10, at least one reference feature 18 may be formed or otherwise provided on a surface 11 of the substrate 10.

The reference feature 18 is shown as a triangle in FIG. 3 merely to facilitate illustration and description herein. It is contemplated, however, that the reference feature 18 may have any arbitrary or any selected shape. In some embodiments, the reference feature 18 may be a naturally-occurring feature on the surface 11 of the substrate 10. In additional embodiments, the reference feature 18 may be a man-made feature formed on the surface 11 of the substrate 10. Various methods known in the art may be used to form the reference feature 18 on the surface 11 of the substrate 10, including, for example, photolithography methods and imprint lithography methods. In additional methods, the reference feature 18 may have an arbitrary shape and may be formed on the surface 11 of the substrate 10 by scratching, scraping, punching, or dying a region on the surface 11 of the substrate. One example of a nanoimprinting process that may be used to form the reference feature 18 on the surface 11 of the substrate 10 is described below with reference to FIGS. 4-8.

Referring to FIG. 4, a substantially bare substrate 10 may be provided, and a layer of deformable material 20 may be deposited or otherwise provided on the surface 11 of the substrate 10. The layer of deformable material 20 may include, for example, a thin layer of poly(methyl methacrylate) (PMMA). The thin layer of deformable material 20 may be applied to the surface 11 of the substrate 10 using, for example, a spin coating process.

Referring to FIG. 5, a nanoimprint mold 12 may be positioned over the substrate 10 and the layer of deformable material 12. A protrusion 14 may extend from an imprinting surface 16 of the nanoimprint mold 12. The protrusion 14 may have a cross-sectional size and shape corresponding to the cross-sectional size and shape of the reference feature 18 (FIG. 3) to be formed on the surface 11 of the substrate 10.

As shown in FIG. 6, the protrusion 14 on the nanoimprint mold 12 may be pressed at least partially into the layer of deformable material 20 to form a corresponding recess 22 in the layer of deformable material 20. The nanoimprint mold 12 then may be removed, as shown in FIG. 7. In some embodiments, the layer of deformable material 20 may be curable, and the deformable material 20 may be cured prior to or after removing the nanoimprint mold 12 from the layer of deformable material 20.

After the nanoimprint mold 12 has been removed from the layer of deformable material 20, an etching process may be used to etch away the deformable material 20 from or at the exposed surfaces thereof until a region 24 on the surface 11 of the underlying substrate 10 is exposed through the layer of deformable material 20, as shown in FIG. 8.

Referring to FIG. 9, material 26 used to form the reference feature 18 on the surface 11 of the substrate 10 may be deposited over the exposed surfaces of the layer of deformable material 20 and the exposed region 24 (FIG. 8) on the surface 11 of the underlying substrate 10. The material 26 may include, but is not limited to, for example, a metal material, a ceramic material, a semiconductive material, or a polymer material. In one particular embodiment, the material 26 may include silica. The material 26 may be deposited using various techniques known in the art, such as, for example, chemical vapor deposition (CVD) or physical vapor deposition (PVD). The remaining portions of the layer of deformable material 20 then may be removed from the surface 11 of the substrate 10 (together with the material 26 deposited thereon), leaving behind the material 26 that has been deposited on the surface 11 of the substrate 10, which forms the reference feature 18 (FIG. 3) on the surface 11 of the substrate 10.

The nanoimprinting process previously described with reference to FIGS. 4 through 9 is set forth merely as an example of one method that may be used to form a reference feature 18 on the surface 11 of the substrate 10. Various other methods for forming features on the surface 11 of a substrate 10 are known in the art (including additional nanoimprinting methods), any of which may be used in the present invention.

After providing one or more reference features 18 on the surface 11 of the substrate 10, a device or structure may be lithographically fabricated on the surface 11 of the substrate 10 using methods and systems that embody teachings of the present invention, as described in further detail below.

With combined reference to FIGS. 1, 2, & 10, the control system 106 of the lithography system 100 may be configured under control of a program to position a first nanoimprint mold 30 proximate the substrate 10 using the positioning system 102, and to acquire a reference image 38 using the imaging system 40 that includes or illustrates at least a portion of the reference feature 18 on the surface 11 of the substrate 10 and at least a portion of a mold alignment feature 32 on a nanoimprinting surface 31 of the first nanoimprint mold 30.

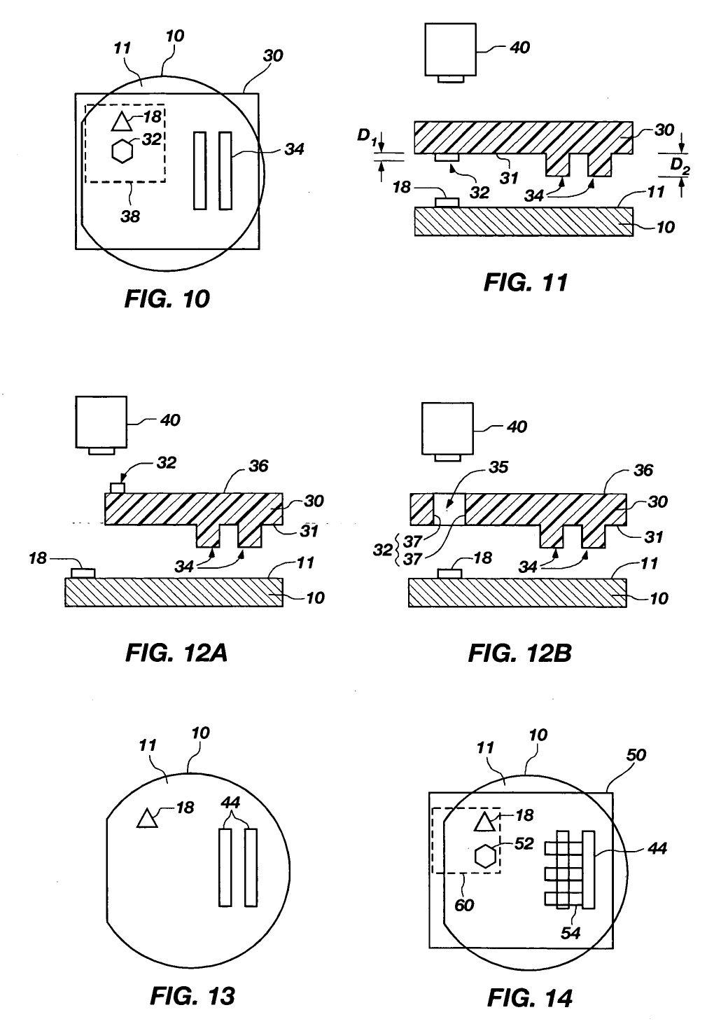

Referring to FIG. 10, the nanoimprint mold 30 may be positioned over the surface 11 of the substrate 10. The nanoimprint mold 30 may include a mold alignment feature 32 and a plurality of device features in the form of protrusions 34, which are configured to form features or elements of a device or structure to be formed on the surface 11 of the substrate 10. FIG. 11 is a cross-sectional view of the nanoimprint mold 30 positioned over the surface 11 of the substrate 10. As shown therein, the mold alignment feature 32 and the plurality of protrusions 34 may extend from a nanoimprinting surface 31 of the nanoimprint mold 30.

When the substrate 10 and the nanoimprint mold 30 are in the relative position shown in FIG. 10 and FIG. 11, a reference image 38 (FIG. 10) may be acquired using the imaging system 40 of the lithography system 100. The reference image 38 may be (or be converted to) a digital image, and the digital image may be stored in an internal or removable memory component of the control system 106 of the lithography system 100 (e.g., read-only memory (ROM) of an internal or external hard drive, internal computer random access memory (RAM), and removable storage media such as, for example, a compact disc (CD), a digital versatile disc (DVD), or a flash memory module), such as the memory device 108, for later use. By way of example and not limitation, the reference image 38 may include the region encompassed by the broken line shown in FIG. 10. The reference image 38 may illustrate at least a portion of the reference feature 18 and at least a portion of the mold alignment feature 32. As shown in FIG. 10, the reference feature 18 and the mold alignment feature 32 each may be entirely illustrated within the reference image 38.

As shown in FIG. 11, in some embodiments, the imaging system 40 may acquire the reference image 38 from a side of the nanoimprint mold 30 opposite the substrate 10. Furthermore, the mold alignment feature 32 of the nanoimprint mold 30 may be disposed on the nanoimprint surface 31 of the nanoimprint mold, and the nanoimprint mold 30 may be disposed between the imaging system 40 and the reference feature 18 on the surface 11 of the substrate 10. In such a configuration, the nanoimprint mold 30 may be transparent to the imaging system 40 so as to enable the imaging system 40 to “see” the reference feature 18 and the mold alignment feature 32 through the nanoimprint mold 30.

By way of example and not limitation, the imaging system 40 may include an optical microscopy system, and the nanoimprint mold 30 may be substantially transparent to visible light (e.g., electromagnetic radiation in the visible region of the electromagnetic spectrum). In an additional embodiment, the imaging system 40 may include an X-Ray system, and the nanoimprint mold 30 may be substantially transparent to X-Rays (e.g., electromagnetic radiation in the X-Ray region of the electromagnetic spectrum). In such a configuration, the relative locations of the reference feature 18 and the mold alignment feature 32 may be identified using the reference image 38.

In an additional embodiment illustrated in FIG. 12A, the nanoimprint mold 30 may be configured or positioned such that a region of the surface 11 of the substrate 10 is exposed to the imaging system 40. In other words, the nanoimprint mold 30 may not be disposed between the imaging system 40 and a portion of the substrate 10. The reference feature 18 may be provided on the region of the surface 11 of the substrate 10 that is exposed to the imaging system 40, and the mold alignment feature 32 may be provided on a back surface 36 of the nanoimprint mold 30, as shown in FIG. 12A. In such a configuration, the nanoimprint mold 30 need not be transparent to the imaging system 40. It may be desirable, however, to minimize the difference between the distance between the imaging system 40 and the reference feature 18 and the distance between the imaging system 40 and the mold alignment feature 32 so as to optimize the degree of focus of both the reference feature 18 and the mold alignment feature 32 in any image acquired by the imaging system 40.

In an additional embodiment illustrated in FIG. 12B, the nanoimprint mold 30 may include an aperture 35 extending therethrough between the back surface 36 and the nanoimprinting surface 31. In this configuration, the mold alignment feature 32 of the nanoimprint mold 30 may include one or more sidewalls 37 of the nanoimprint mold 30 within the aperture 35. The reference feature 18 on the substrate 10 may be provided on a region of the surface 11 of the substrate 10 that is exposed to the imaging system 40 through the aperture 35 extending through the nanoimprint mold 30. In such a configuration, the nanoimprint mold 30 need not be transparent to the imaging system 40, and the imaging system 40 may be used to acquire an image that illustrates both the reference feature 18 on the substrate 10 (visible to the imaging system 40 through the aperture 35) and the mold alignment feature 32 (as defined by one or more sidewalls 37 of the nanoimprint mold 30 within the aperture 35). In additional embodiments, a mold alignment feature 32 (such as that shown in FIG. 12A) may be provided on the back surface 36 of the nanoimprint mold 30 shown in FIG. 12B, and the imaging system 40 may be used to acquire an image that illustrates both the reference feature 18 on the substrate 10 (visible to the imaging system 40 through the aperture 35) and the mold alignment feature 32 on the back surface 36 of the nanoimprint mold 30.

Referring again to FIG. 2, after acquiring and storing the reference image 38 (FIG. 10), the lithography system 100 (FIG. 1) may be configured under control of a program to process the substrate 100 with the first nanoimprint mold 30. For example, the nanoimprint mold 30 may be used to form features of a device or structure being formed on the surface 11 of the substrate 10. When forming the features of a device or structure on the surface 11 of the substrate 10 using the nanoimprint mold 30, relative movement between the nanoimprint mold 30 and the substrate 10 may substantially be limited to movement in a direction substantially perpendicular to the surface 11 of the substrate 10. In so doing, the reference image 38 may closely represent the relative positioning of features on the substrate 10 following imprinting on the substrate 10 using the mold 30. As a result, information may be extracted from the reference image 38, which may be used to precisely align the features formed using the nanoimprint mold 30 on the surface 11 of the substrate 10 with additional features subsequently formed in overlying layers using one or more additional nanoimprint molds, as described below.

As described above, the reference image 38 may be acquired prior to forming the features of a device or structure on the surface 11 of the substrate 10 using the nanoimprint mold 30. In additional embodiments of the present invention, the reference image 38 may be acquired after forming the features of a device or structure on the surface 11 of the substrate 10 using the nanoimprint mold 30, or while forming the features of a device or structure on the surface 11 of the substrate 10 using the nanoimprint mold 30. Any reference image 38 from which information can be extracted and used to precisely align features formed on the substrate 10 (using the nanoimprint mold 30 or any other tool) with additional features subsequently formed in overlying layers (using one or more additional nanoimprint molds or other tools) may be used according to the present invention.

FIG. 13 illustrates the substrate 10 including a first set of device features 44 formed on, in, or over the surface 11 of the substrate 10 using the nanoimprint mold 30. By way of example and not limitation, a plurality of integrated circuits may be fabricated in, on, or over the surface 11 of the substrate 10, and the device features 44 may include one or more of conductive lines or traces, conductive pads, conductive vias, and elements or portions of active components (such as, for example, transistors) of the integrated circuits. The device features 44 (and the reference feature 18) have been greatly enlarged and simplified to facilitate illustration and description herein. In actuality, the device features 44 (and the reference feature 18) may be extremely small relative to the substrate 10. Furthermore, device features 44 may be formed across a substantial portion of the surface 11 of the substrate 10, and not just over a relatively small area, as shown in FIG. 13.

As shown in FIG. 13, in some embodiments of the present invention, the substrate 10 may not be marked in any way by the mold alignment feature 32 of the nanoimprint mold 30 (FIGS. 10-11). Referring again to FIG. 11, in some embodiments of the present invention, the mold alignment feature 32 of the nanoimprint mold 30 may extend from the nanoimprinting surface 31 of the nanoimprint mold 30 by a first distance D₁ and the protrusions 34 may extend from the nanoimprinting surface 31 of the nanoimprint mold 30 by a second distance D₂. As shown in FIG. 11, the first distance D₁ may be less than the second distance D₂. By way of example and not limitation, the ratio of the first distance D₁ to the second distance D₂ may be less than about 0.5. More particularly, the ratio of the first distance D, to the second distance D₂ may be less than about 0.3. In this configuration, it may be possible to process the substrate 10 using the nanoimprint mold 30 without forming a mark on the substrate 10 that corresponds to the mold alignment feature 32. In particular, the protrusions 34 may be pressed into a layer of deformable material by a distance that is less than the difference between the second distance D₂ and the first distance D₁ (i.e., D₂−D₁). As such, the mold alignment feature 32 may not be pressed into the layer of deformable material when the protrusions 34 are pressed into the layer of deformable material. In addition, even if the mold alignment feature 32 is pressed into the layer of deformable material during an imprinting process, the corresponding recess or impression formed in the layer of deformable material may be relatively shallow relative to the recesses or impressions formed by the protrusions 34. As a result, during subsequent processing, the relatively shallow recess or impression formed by the mold alignment feature 32 may not result in the formation of a corresponding feature in, on, or over the surface 11 of the substrate 10.

The ability of the system to accurately align additional lithography tools relative to the substrate may be enhanced by using nanoimprint molds or other lithography tools that are configured to not mark the substrate 10 when the substrate 10 is processed using the nanoimprint molds or other lithography tools, as discussed in further detail below.

The reference image 38 acquired using the imaging system 40 may be used to ensure proper alignment of additional device features with the underlying device features 44 as the additional device features are formed using additional nanoimprint molds or other lithography tools.

Referring again to FIGS. 1-2 together with FIG. 14, after processing the substrate 10 with the first nanoimprint mold 30, the control system 106 of the lithography system 100 may be configured under control of a program to position an additional nanoimprint mold 50 relative to the substrate 10 using the positioning system 102, and to acquire an alignment image 60 using the imaging system 40. The alignment image 60 may include or illustrate at least a portion of the reference feature 18 on the surface 11 of the substrate 10 and at least a portion of an alignment feature 52 on a surface of the additional lithography tool 50.

For example, the additional nanoimprint mold 50 may be positioned over the substrate 10, as shown in FIG. 14. The additional nanoimprint mold 50 may include a mold alignment feature 52 and a plurality of design features in the form of protrusions 54 that are generally similar to the previously described mold alignment feature 32 and protrusions 34 of the nanoimprint mold 30. In some embodiments, the body of the additional nanoimprint mold 50 may have a size and shape that is substantially identical to the size and shape of the body of the nanoimprint mold 30.

Initially, the additional nanoimprint mold 50 may be only roughly aligned with the underlying substrate 10. An alignment image 60 may be acquired using the imaging system 40 in a manner substantially similar to that previously described in relation to the reference image 38 and FIG. 11. In additional embodiments, the alignment image 60 may be acquired using an additional imaging system (not shown). The alignment image 60 may be a “live” image (i.e., stored in random access memory of the control system 106), or the alignment image 60 may be “stored” in memory of the control system 106, such as the memory device 108, as previously described in relation to the reference image 38. The alignment image 60 may include at least a portion of the reference feature 18 on the substrate 10 and at least a portion of the mold alignment feature 52 on the additional nanoimprint mold 50. It may be necessary or desirable to ensure that a similar or substantially identical degree of focus is achieved by the imaging system 40 when the imaging system 40 is used to acquire the reference image 38 and each alignment image 60.

It may be necessary or desirable to ensure that the reference feature 18 on the surface 11 of the substrate 10 does not change appearance in the various images acquired using the imaging system 40 of the lithography system 100. As such, the reference mark 18 on the surface 11 of the substrate 10 may not be affected or altered in any way as the substrate 10 is processed using the first nanoimprint mold 30 or any additional nanoimprint mold 50. For example, any material deposited over the reference mark 18 when processing the substrate 10 using the first nanoimprint mold 30 or any additional nanoimprint mold 50 may be removed before positioning any subsequent nanoimprint molds over the substrate 10, acquiring an additional alignment image 60, and processing the substrate 10 using the subsequent nanoimprint molds.

In some embodiments, the mold alignment feature 52 on the additional nanoimprint mold 50 may be substantially identical to the mold alignment feature 32 on the first nanoimprint mold 30, and the mold alignment feature 52 and the mold alignment feature 32 may be provided at substantially identical respective locations on the nanoimprint mold 50 and the nanoimprint mold 30. Such is not necessary, however, and in some embodiments, the mold alignment feature 52 may differ from the mold alignment feature 32 in at least one aspect. Furthermore, the mold alignment feature 52 and the mold alignment feature 32 may be provided at different respective locations on the nanoimprint mold 50 and the nanoimprint mold 30. In such a case, the differences may be accounted for when aligning the nanoimprint molds as long as the relative locations of the mold alignment feature and the protrusions on the imprinting surface (that are configured to form device features on the substrate 10) are known, at least well enough for an initial alignment, for each respective nanoimprint mold. In some embodiments, the mold alignment feature 32 and the mold alignment feature 52 may be provided at different respective locations on the nanoimprint mold 30 and the nanoimprint mold 50 if the mold alignment feature 32 is configured to mark the surface of the substrate 10. In this configuration, any mark formed on the substrate 10 by the mold alignment feature 32 may be less likely to interfere with identification of the mold alignment feature 52 in the alignment image 60.

Referring again to FIGS. 1-2, after acquiring the alignment image 60 (FIG. 14), the control system 106 of the lithography system 100 may be configured under control of a program to compare the alignment image 60 to the reference image 38 and to determine whether the additional nanoimprint mold 50 is properly aligned.

For example, the alignment image 60 (FIG. 14), together with the previously acquired reference image 38 (FIG. 10), may be used to determine whether the protrusions 54 are precisely aligned with the underlying device features 44 previously formed in, on, or over the surface 11 of the substrate 10. If the protrusions 54 are not precisely aligned with the underlying device features 44, the alignment image 60 and the reference image 38 may be used to determine the magnitude and direction of the relative lateral displacement (or misalignment) between the protrusions 54 and the underlying device features 44, as described in further detail below. For example, the control system 106 of the lithography system 100 may be used to perform one or more algorithms using the reference image 38 and the alignment image 60 to precisely align the protrusions 54 with the previously formed underlying device features 44. Such algorithms may include displacement sensing and estimation (DSE) algorithms, and in particular, nanoscale displacement sensing and estimation (nDSE) algorithms. Such algorithms may include, for example, an image cross-correlation algorithm, a phase delay detection algorithm, or other displacement sensing and estimation algorithms.

One example of an image cross-correlation algorithm is a nearest neighbor navigation algorithm. In a nearest neighbor navigation algorithm, the control system 106 may be configured under control of a program to use image cross-correlations or comparison functions which approximate or parallel pixel-by-pixel correlation functions to calculate the displacement. The nearest neighbor navigation algorithm uses very short correlation distances in calculating the displacement. Additional details of nearest neighbor navigation algorithms may be found in U.S. Pat. No. 5,149,980 to Ertel et al., which is entitled “SUBSTRATE ADVANCE MEASUREMENT SYSTEM USING CROSS-CORRELATION OF LIGHT SENSOR ARRAY SIGNALS,” and U.S. Pat. No. 6,195,475 to Beausoleil et al., which is entitled “NAVIGATION SYSTEM FOR HANDHELD SCANNER,” the contents of each of which are hereby incorporated herein in their entirety by this reference. Each of these patents is assigned to the assignee of the present invention.

In a phase delay detection algorithm (and other similar phase correlation methods), the control system 106 may be configured under control of a program to process images in frequency space and to draw equivalences between phase delays and displacements to calculate the displacement.

In additional embodiments, the control system 106 may be configured under control of a program to calculate geometric extractions, such as edges and centerlines, from the reference feature 18 and the mold alignment features 32, 52. In these embodiments, the control system 106 may be configured under control of a program to calculate the displacements using the geometric extractions.

As one example of a method for using the reference image 38 and the alignment image 60 to precisely align the protrusions 54 with the previously formed underlying device features 44, the control system 106 may be used to calculate a displacement vector for the nanoimprint mold 50. As used herein, the term “displacement vector” means any graphical, numerical, or mathematical expression of a distance and direction that the nanoimprint mold 50 may be moved to more accurately align the protrusions 54 of the nanoimprint mold 50 with the previously formed device features 44.

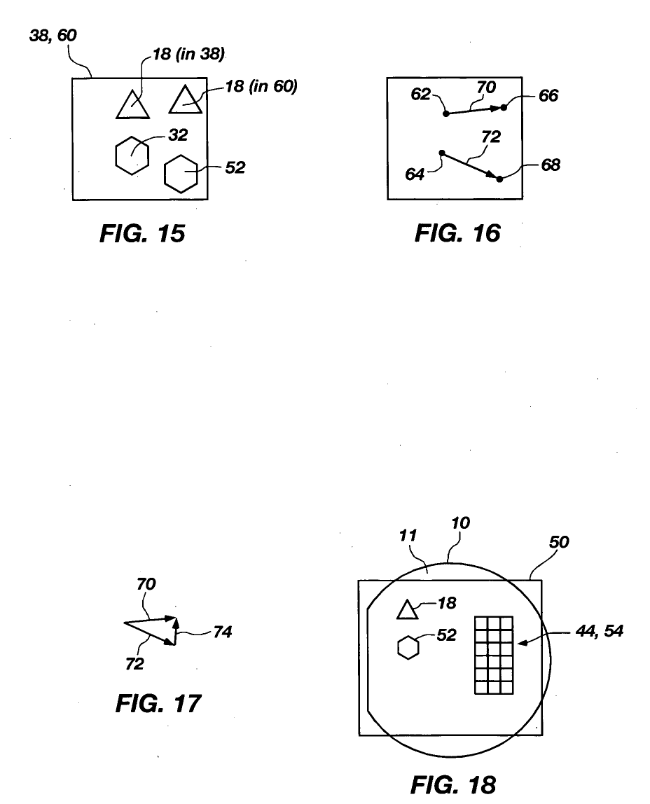

One example of a manner in which the control system 106 may be used to calculate a displacement vector for the nanoimprint mold 50 may be described with reference to FIGS. 15-17. FIG. 15 illustrates the alignment image 60 laid over the reference image 38. As shown in FIG. 15, the position of the alignment feature 18 in the alignment image 60 may be different from the position of the alignment feature 18 in the reference image 38. Similarly, the position of the mold alignment feature 52 in the alignment image 60 may be different from the position of the mold alignment feature 32 in the reference image 38. In additional methods, the position of the alignment feature 18 in the alignment image 60 may overlap with, or may be the same as, the position of the alignment feature 18 in the reference image 38.

Referring to FIG. 16, a computer device may be used to perform one or more algorithms on each of the reference image 38 and the alignment image 60 to identify a point 62 representing the location of the reference feature 18 in the reference image 38, a point 64 representing the location of the mold alignment feature 32 in the reference image 38, a point 66 representing the location of the reference feature 18 in the alignment image 60, and a point 68 representing the location of the mold alignment feature 52 in the alignment image 60. A first vector 70 may be defined between the point 62 and the point 66, and a second vector 72 may be defined between the point 64 and the point 68. Referring to FIG. 17, a displacement vector 74 for the nanoimprint mold 50 may be obtained by subtracting the second vector 72 from the first vector 70, as represented in FIG. 17.

It is understood that the points 62, 64, 66, and 68 may be determined when each of the reference mark 18, the mold alignment feature 32, and the mold alignment feature 52 have at least one well defined geometrical feature (e.g., a clear center point, an edge, etc.). In additional embodiments and methods, one or more of the reference mark 18, the mold alignment feature 32, and the mold alignment feature 52 may comprise a substantially arbitrary shape or feature. In such cases, the first vector 70 and the second vector 72 described above may be derived using displacement sensing techniques known in the art, thereby eliminating the need to identify the points 62, 64, 66, and 68 to derive the first vector 70 and the second vector 72. It is contemplated, that such displacement sensing techniques also may be when the reference mark 18, the mold alignment feature 32, and the mold alignment feature 52 each have at least one well defined geometrical feature.

The displacement vector 74 represents a distance and a direction that the nanoimprint mold 50 (FIG. 14) may be moved relative to the substrate 10 (or the substrate 10 moved relative to the nanoimprint mold 50) to more precisely align the protrusions 54 of the nanoimprint mold 50 with the previously formed underlying device features 44.

In additional embodiments, the control system 106 may not directly analyze and compare the locations of the reference feature 18 and the mold alignment features 32, 52 in the reference image 38 and the alignment image 60. In some embodiments, the control system 106 may be configured under control of a program to execute an algorithm that processes and analyzes substantially the entire field of each of the reference image 38 and the alignment image 60. The control system 106 may be configured under control of a program to slightly adjust the relative position between the substrate 10 and the additional nanoimprint mold 50 between each iteration of the algorithm, and to “hunt” for the configuration or relative position that provides the highest correlation between the reference image 38 and the alignment image 60. The control system 106 may be configured to adjust the relative position between the substrate 10 and the additional nanoimprint mold 50 between each iteration in an exhaustive predetermined pattern. Alternatively, the control system 106 may be configured to execute an algorithm between each iteration that determines a direction movement that is likely to increase the degree of correlation between the reference image 38 and the alignment image 60 only until a predetermined acceptable level of correlation is achieved.

Any method or algorithm that can be used to compare the reference image 38 with the alignment image 60, and that can be used to determine a direction and a distance by which one or both of the substrate 10 and the additional nanoimprint mold 50 may be moved so as to improve the alignment therebetween, may be used in methods that embody teachings of the present invention, such as those previously described herein.

It is contemplated that any global offsets between the reference image 38 (FIG. 10) and each alignment image 60 (FIG. 14) may be ignored, subtracted-out, or minimized when comparing the reference image 38 to each alignment image 60. For example, the algorithm carried out by the control system 106 when comparing each alignment image 60 to the reference image 38 may be configured to identify any global offset between the reference image 38 and the alignment image 60 and to subtract the global offset from one or both of the first vector 70 and the second vector 72 (FIG. 17) when performing the previously described vector analysis to determine the displacement vector 74. In addition or as an alternative, the position and orientation of the imaging system 40 may be adjusted as necessary immediately prior to acquiring each alignment image 60 to reduce or minimize the global offset between the reference image 38 and each respective alignment image 60. In other words, at least one of the imaging system 40, the nanoimprint mold 50, and the substrate 10 may be moved until the mark 18 in both reference image 38 and the alignment image 60 is in the same location, or until both the mold alignment feature 32 and the mold alignment feature 52 are in the same location in both reference image 38 and the alignment image 60, respectively, or until the mark 18 is in the same location and the mold alignment feature 32 and the mold alignment feature 52 are in the same location. The accuracy of the alignment of each additional nanoimprint mold 50 may be enhanced by minimizing global offsets between the reference image 38 and each respective alignment image 60.

Referring again to FIGS. 1-2, after determining whether the additional nanoimprint mold 50 is properly aligned, the control system 106 of the lithography system 100 may be configured under control of a program to adjust the position of the additional nanoimprint mold 50 relative to the substrate 10 if the additional nanoimprint mold 50 is not properly aligned, and to process the substrate 10 with the additional nanoimprint mold 50 if the additional nanoimprint mold 50 is properly aligned.

For example, referring again to FIG. 14, if the nanoimprint mold 50 is not properly positioned, the control system 106 of the lithography system 100 may move or adjust the position of the nanoimprint mold 50 relative to the substrate 10 (or the substrate 10 may be moved relative to the nanoimprint mold 50) in the direction and by the distance corresponding to the displacement vector 74 (FIG. 17) using the positioning system 102.

FIG. 18 illustrates the nanoimprint mold 50 positioned over the substrate 10 after moving the nanoimprint mold 50 relative to the substrate 10 (or moving the substrate 10 relative to the nanoimprint mold 50) in the direction and by the distance corresponding to the displacement vector 74 (FIG. 17). As can be shown by comparison of FIG. 14 and FIG. 18, the protrusions 54 of the nanoimprint mold 50 may be more precisely aligned with the previously formed underlying device features 44 after adjusting the relative positions of the nanoimprint mold 50 and the substrate 10 according to the displacement vector 74 (FIG. 17).

As shown in FIG. 2, after adjusting the position of the additional nanoimprint mold 50 relative to the substrate 10, another alignment image (similar to the alignment image 60 shown in FIG. 14) may be acquired and compared to the reference image 38 to determine whether the additional nanoimprint mold 50 is properly aligned. This process may be repeated as necessary until the additional nanoimprint mold 50 is properly aligned. In this manner, alignment measurements may be taken repeatedly to provide feedback to the positioning system 102 of the lithography system 100 as the positioning system 102 adjusts the position of the additional nanoimprint mold 50 relative to the substrate 10 until a predetermined acceptable level of alignment is achieved for the additional nanoimprint mold 50. Once the additional nanoimprint mold 50 is properly aligned, the control system 106 of the lithography system 100 (FIG. 1) may be configured to process the substrate 10 using the additional nanoimprint mold 50.

With continued reference to FIG. 2, after processing the substrate 10 with the additional nanoimprint mold 50, it may be determined whether additional layers of features are to be formed in, on, or over the substrate 10. To complete the fabrication of a device or structure (such as, for example, an integrated circuit) on the surface 11 of the substrate 10, a plurality of layers of features may be fabricated in a layer-by-layer process over the first layer of features 44. To ensure proper fabrication of the device or structure comprising the plurality of layers of features, it may be necessary or desirable to ensure that each layer of features is precisely aligned with the underlying layer or layers of features.

If additional layers of features are to be formed over the substrate 10, at least a portion of the previously described sequence may be repeated. For example, the sequence may be repeated, beginning at operation box 80, by positioning yet an additional nanoimprint mold (not shown) that is generally similar to the additional nanoimprint mold 50 (FIG. 14) relative to the substrate 10.

In some embodiments of the present invention, it may be desirable to refresh the reference image 38 (FIG. 10) after forming a predetermined number of layers of features using nanoimprint molds. In other words, it may be desirable to refresh the reference image 38 after forming “R” layers of features (where R is any integer greater than 1). In such a situation, the control system 106 may be configured under control of a program to maintain an integer counter. By way of example and not limitation, such an integer counter may be initially set to zero or any number. As shown in FIG. 2, after processing the substrate with each additional nanoimprint mold (lithography tool), the integer counter may be incremented (e.g., from 0 to 1, from 1 to 2, from 2 to 3, etc.). After incrementing the integer counter, it may be determined whether additional layers of features are to be formed in, on, or over the substrate 10. If additional layers of features are to be formed, it may be determined whether the expression (C MOD R) is equal to zero (0), where R is the selected number of layers to be formed prior to refreshing the reference image and C is the integer value of the integer counter. As used herein, the expression (C MOD R) means the remainder of C divided by R. As one example, if it is desired to refresh the reference image after forming four (4) layers of features, R is equal to four (4), and each time the counter is an integer multiple of four (4), the expression (C MOD R) will be equal to zero. In each such instance, the sequence may be repeated, beginning at operation box 82, by positioning the next nanoimprint mold (lithography tool) relative to the substrate 10 and acquiring a new reference image 38 that includes at least a portion of the reference feature 18 on the substrate 10 and at least a portion of an alignment feature on the particular nanoimprint mold positioned relative to the substrate 10. The sequence then may be continued as previously described.

In additional embodiments, it may be desirable to refresh the reference image 38 at various selected stages in a process in which a number of layers of features are formed using nanoimprint molds. For example, in a multilayer structure, it may be relatively more critical to align device features in one layer relative to device features in an adjacent layer, as opposed to aligning the device features relative to the device features in the first layer (the layer formed immediately after acquiring the reference image 38). As such, the reference image 38 may be refreshed at various intervals in a manufacturing process as necessary or desired.

It is contemplated that in some situations, precise alignment between the substrate 10 and the first layer of device features 44 formed thereon may not be critical. In such situations, only precise alignment between the various layers of device features 44, 54 may be critical. In such cases, the reference feature 18 may comprise one or more of the first layer device features 44.

In some embodiments of the present invention, the mold alignment feature 32 and mold alignment feature 52 each may have a simple geometric shape, as shown in FIG. 15. In some embodiments of the present invention, the mold alignment feature 52 on the additional nanoimprint mold 50 may be different from, but complementary to, the mold alignment feature 32 on the first nanoimprint mold 30. By way of example and not limitation, the mold alignment feature 32 on the first nanoimprint mold 30 may include a box and the mold alignment feature 52 on the additional nanoimprint mold 50 (and any other additional nanoimprint molds used to process the substrate 10) may include a cross. In such a configuration, the reference image 38 may include the reference feature 18 and the box providing the mold alignment feature 32, and the alignment image 60 may include the reference feature 18 and the cross providing the mold alignment feature 52. When comparing the reference image 38 and the alignment image 60, the algorithm performed by the control system 106 to align the additional nanoimprint mold 50 may be configured to center the cross (mold alignment feature 52) within the box (mold alignment feature 32). In some of these additional embodiments, the box providing the mold alignment feature 32 may be configured to mark a surface of the substrate 10. In other words, a box may be formed on the substrate 10 after processing the substrate 10 with the first nanoimprint mold 30. In such a configuration, the control system 106 may be configured under control of a program to center the cross (mold alignment feature 52) of each additional nanoimprint mold within the box formed on the substrate by the mold alignment feature 32 of the first nanoimprint mold 30. In such embodiments, the algorithm may be configured to perform a geometric abstraction processes (e.g., an edge-detection process) or a shape-fitting process instead of, or in addition to, simple image cross-correlation processes.

It is not necessary to use a cross and box configuration, and any pattern or form having a defined center may be used for the mold alignment feature 32 and the mold alignment feature 52. Furthermore, patterns or forms that do not have a defined center also may be used for the mold alignment feature 32 and the mold alignment feature 52 if the control system 106 is capable of determining the locations and orientations of the patterns or forms using an algorithm and the identified patterns or forms. In additional embodiments, the shapes of the mold alignment feature 32 and the mold alignment feature 52 may not be identical or complementary, and the mold alignment feature 52 may have a shape that differs from a shape of the mold alignment feature 32.

Furthermore, while the invention has been described using a single reference feature 18 on the substrate 10 and a single mold alignment feature 32 on the first nanoimprint mold 30 and a single mold alignment feature 52 on the additional nanoimprint mold 50, it is contemplated that a plurality of corresponding reference features and mold alignment features may be used to facilitate or enhance rotational alignment between a substrate and lithography tools. In additional embodiments, algorithms capable of determining the relative rotation (e.g., polar-coordinate phase correlation) between images (e.g., the reference image 38 and the alignment image 60) may be used to facilitate or enhance rotational alignment. In some methods, it may be necessary or desirable to establish acceptable rotational alignment prior to establishing translational alignment in a plane generally parallel to the surface 11 of the substrate 10.

As previously discussed, the reference feature 18 on the substrate 10 and each alignment feature on each respective lithography tool (e.g., the mold alignment feature 32 on the nanoimprint mold 30 and the mold alignment feature 52 on the nanoimprint mold 50) may be natural or man-made, and may have any random or predetermined shape. The ability of the lithography system 100 (FIG. 1) to precisely align each lithography tool may be improved by providing the alignment features on each respective lithography tool proximate to the location of each corresponding reference feature on the substrate.

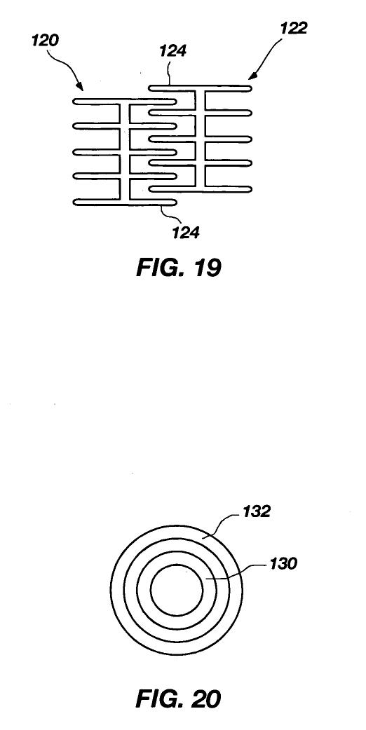

In some embodiments, each alignment mark on a lithography tool may be positioned to appear intertwined with a respective reference mark on the substrate in the images acquired by the imaging system 40. For example, as shown in FIG. 19, a reference mark 120 on a substrate and a corresponding alignment mark 122 on a lithography tool each may include a plurality of intertwining features or extensions 124. In yet additional embodiments, each alignment mark on a lithography tool may be positioned to appear at a complementary location with respective to reference mark on the substrate in the images acquired by the imaging system 40. For example, as shown in FIG. 20, a reference mark 130 on a substrate may have an annular shape, and a corresponding alignment mark 132 on a lithography tool may also have an annular shape. The annular-shaped alignment mark 132 on the lithography tool may have a diameter that is larger than a diameter of the annular-shaped reference mark, such that the alignment mark 132 and the reference mark 130 appear to be concentrically located in images acquired by the imaging system 40 when the lithography tool carrying the alignment mark 132 is properly aligned with the substrate carrying the reference mark.

Methods for aligning lithography tools with a substrate, and more particularly, methods for aligning features on such lithography tools with previously formed features on such a substrate, have been described herein primarily in relation to nanoimprint lithography tools and methods. It is understood that the methods previously described herein may be used with any other type of lithography tools and methods in which lithography tools must be aligned with a substrate. For example, the methods previously described herein may be used to align photolithography masks and reticles with an underlying substrate on which one or more structures or devices (such as, for example, an integrated circuit) are being fabricated.

By comparing alignment images with reference images, the methods and systems described herein may provide layer-to-layer alignment for each fabricated layer, as opposed to layer-to-substrate alignment for each fabricated layer. The methods and systems described herein may provide a means for overcoming metrology error that is attributable to changes in conventional alignment marks that are caused by processing (often referried to as wafer-induced shift (WIS)). In this manner, the methods and systems described herein may provide improved alignment between features in adjacent layers relative to known methods and systems.

The methods described herein may be further enhanced by verifying alignment of device features formed on a substrate using the methods and systems described herein using an external tool or system, such as, for example a scanning-electron microscope (SEM) or a transmission electron microscope (TEM). Systematic errors may be identified that are caused by the lithography system (e.g., post-alignment lateral shifts) and/or the metrology system or method. Systematic errors that are identified by external verification may be offset by selectively modifying the displacement vector 74 (FIG. 17). In this manner, the alignment accuracy of the systems and methods described herein may be further enhanced.

Although the foregoing description contains many specifics, these are not to be construed as limiting the scope of the present invention, but merely as providing certain representative embodiments. Similarly, other embodiments of the invention can be devised which do not depart from the spirit or scope of the present invention. The scope of the invention is, therefore, indicated and limited only by the appended claims and their legal equivalents, rather than by the foregoing description. All additions, deletions, and modifications to the invention, as disclosed herein, which fall within the meaning and scope of the claims, are encompassed by the present invention.

What is claimed is:

1. A method of performing lithography comprising:
calculating a displacement vector for a lithography tool using an image illustrating at least a portion of the lithography tool and at least a portion of a substrate, and an additional image illustrating at least a portion of an additional lithography tool and at least a portion of the substrate.

2. The method of claim 1, further comprising adjusting a position of the lithography tool in response to the displacement vector.

3. The method of claim 1, wherein calculating a displacement vector comprises performing an image cross-correlation algorithm or a phase delay detection algorithm using a computer system.

4. The method of claim 1, wherein calculating a displacement vector comprises performing a geometric extraction algorithm or a shape-fitting algorithm using a computer system.

5. The method of claim 1, wherein calculating a displacement vector for a lithography tool comprises calculating a displacement vector for a mask, reticle, or imprint mold.

6. A method of aligning objects relative to one another, the method comprising:
providing a first object having a feature on a surface of the first object;
positioning a second object proximate the first object, the second object having a feature on a surface of the second object;
acquiring a first image illustrating the feature on the surface of the first object and the feature on the surface of the second object;
positioning at least one additional object proximate the first object, the at least one additional object having a feature on a surface of the at least one additional object;
acquiring an additional image illustrating the feature on the surface of the first object and the feature on the surface of the at least one additional object; and
comparing the additional image with the first image.

7. The method of claim 6, wherein comparing the additional image to the first image comprises calculating a displacement vector.

8. The method of claim 7, wherein calculating a displacement vector comprises:
calculating a first vector defining a relative position between the feature on the surface of the first object in the first image and the feature on the surface of the first object in the additional image;
calculating a second vector defining a relative position between the feature on the surface of the second object in the first image and the feature on the surface of the at least one additional object in the additional image; and
subtracting at least one of the first vector and the second vector from the other of the first vector and the second vector.

9. The method of claim 7, further comprising:
adjusting a position of the at least one additional object in response to the displacement vector.

10. The method of claim 6, wherein positioning at least one additional object proximate the first object comprises sequentially positioning a plurality of additional objects proximate the first object, each additional object of the plurality of additional objects having a feature on a surface thereof, and wherein acquiring an additional image comprises sequentially acquiring a plurality of additional images, each additional image of the plurality of additional images illustrating the feature on the surface of the first object and a feature on the surface of an additional object of the plurality of additional objects.

11. The method of claim 10, further comprising comparing each additional image of the plurality of additional images with the first image.

12. The method of claim 10, further comprising:
comparing at least one additional image of the plurality of additional images to another additional image of the plurality of additional images;
calculating a displacement vector using the at least one additional image and the another additional image.

13. The method of claim 12, further comprising:
adjusting a position of at least one additional object of the plurality of additional objects in response to the displacement vector.

14. The method of claim 6, wherein providing a first object comprises providing a substrate, positioning a second object comprises positioning a mask or reticle; and positioning at least one additional object comprises positioning at least one additional mask or reticle.

15. The method of claim 6, wherein providing a first object comprises providing a substrate, positioning a second object comprises positioning an imprint mold; and positioning at least one additional object comprises positioning at least one additional imprint mold.

16. The method of claim 6, wherein acquiring a first image and acquiring an additional image each comprise acquiring a visible image using an optical microscope.

17. A lithography system comprising:
a positioning system;
an imaging system; and
a control system configured to selectively control the positioning system and the imaging system, the control system configured under control of a program to:
position a first lithography tool proximate a substrate using the positioning system;
acquire a first image illustrating a feature on a surface of the substrate and a feature on a surface of the first lithography tool;
position at least one additional lithography tool proximate the substrate;
acquire an additional image illustrating the feature on the surface of the first object and a feature on a surface of the at least one additional lithography tool; and
calculate a displacement vector using the first image and the additional image.

18. The lithography system of claim 17, wherein the imaging system comprises an optical microscope.

19. The lithography system of claim 17, wherein the control system comprises a desktop computer, a laptop computer, or a programmable logic controller.

20. The lithography system of claim 17, wherein the control system is further configured under control of the program to adjust a position of the at least one additional lithography tool in response to the displacement vector.

21. The lithography system of claim 17, wherein the control system is configured under control of the program to:
position a plurality of additional lithography tools proximate the substrate; and
acquire a plurality of additional images, each additional image of the plurality of additional images illustrating the feature on the surface of the substrate and a feature on a surface of an additional lithography tool of the plurality of additional lithography tools.

22. The lithography system of claim 21, wherein the control system is configured under control of the program to:
calculate a plurality of displacement vectors, each displacement vector of the plurality of displacement vectors being calculated using the first image and an additional image of the plurality of additional images.

23. The lithography system of claim 17, wherein the lithography system comprises a photolithography system or an imprint lithography system.

24. An imprint mold comprising:
an imprinting surface;
a plurality of device features protruding from the imprinting surface by a substantially uniform distance; and
at least one non-marking alignment feature on the imprinting surface, the non-marking alignment feature extending from the imprinting surface by a distance that is less than the substantially uniform distance.

25. The imprint mold of claim 24, wherein at least a portion of the mold comprising the at least one non-marking alignment feature is substantially transparent to at least one range of wavelengths of electromagnetic radiation between about 400 nanometers and about 800 nanometers.
